(19) United States
(12) Patent Application Publication
(10) Pub. No.: US 2025/0127022 A1
(43) Pub. Date: Apr. 17, 2025

(54) DISPLAY DEVICE AND METHOD OF FABRICATING THE SAME

(71) Applicant: Samsung Display Co., LTD., Yongin-si (KR)

(72) Inventor: Hyun Eok SHIN, Yongin-si (KR)

(21) Appl. No.: 18/765,058

(22) Filed: Jul. 5, 2024

(30) Foreign Application Priority Data
Oct. 16, 2023 (KR) 10-2023-0137813
Mar. 11, 2024 (KR) 10-2024-0033699

(51) Int. Cl. H10K 59/80; G06F 3/041; H10K 59/12; H10K 59/40

(52) U.S. Cl. CPC H10K 59/8791; G06F 3/0412; H10K 59/1201; H10K 59/40

(57) ABSTRACT

A display device includes a substrate including an emission area and a non-emission area, a touch-insulating layer above the substrate, a touch electrode above the touch-insulating layer, overlapping the non-emission area, and including a first conductive layer contacting the touch-insulating layer, a second conductive layer above the first conductive layer, and including a conductive material that is different from a conductive material of the first conductive layer, and a metal oxide layer on a side surface of the second conductive layer facing the emission area, contacting the side surface of the second conductive layer, and not contacting an upper surface of the second conductive layer facing a touch protection layer, and a touch protection layer above the touch-insulating layer and the touch electrode.

### CROSS-REFERENCE TO RELATED APPLICATION

The present application claims priority to, and the benefit of, Korean Patent Application No. 10-2023-0137813, filed on Oct. 16, 2023, and No. 10-2024-0033699, filed on Mar. 11, 2024, in the Korean Intellectual Property Office, the entire disclosure of which is incorporated herein by reference.

### BACKGROUND

### 1. Field

The present disclosure relates to a display device and a method of fabricating the same.

### 2. Description of the Related Art

As the information society develops, the demand for display devices for displaying images has increased and diversified. For example, display devices have been applied to various electronic devices, such as smartphones, digital cameras, laptop computers, navigation devices, and smart televisions.

Recently, mainly in smartphones and tablet personal computers (PCs), touch members that recognize touch input have been applied to display devices. Such a touch member has been formed directly on a display panel to promote simplification of a process and thinness of the display device.

The display device includes a display panel that generates and displays an image and various input devices. Recently, mainly in smartphones or tablet PCs, a touch panel that recognizes touch input has been widely applied to the display device. The touch panel decides whether or not input has been generated, and calculates a corresponding position as input coordinates.

### SUMMARY

Aspects of the present disclosure provide a display device that solves a reliability defect perceived as reddish from the outside of the display device by reducing side reflected light of touch wiring, and a method of manufacturing the same.

According to one or more embodiments of the present disclosure, a display device includes a substrate including an emission area and a non-emission area, a touch-insulating layer above the substrate, a touch electrode above the touch-insulating layer, overlapping the non-emission area, and including a first conductive layer contacting the touch-insulating layer, a second conductive layer above the first conductive layer, and including a conductive material that is different from a conductive material of the first conductive layer, and a metal oxide layer on a side surface of the second conductive layer facing the emission area, contacting the side surface of the second conductive layer, and not contacting an upper surface of the second conductive layer facing a touch protection layer, and a touch protection layer above the touch-insulating layer and the touch electrode.

The second conductive layer may include copper, wherein the metal oxide layer includes copper oxide.

The metal oxide layer may entirely cover the side surface of the second conductive layer.

A width of the metal oxide layer in a direction parallel to the substrate may be substantially uniform within about 5%.

A height of the first conductive layer in a direction perpendicular to the substrate may be less than a height of the second conductive layer.

The first conductive layer may include any one of a molybdenum-titanium-nickel alloy (MTD alloy), titanium, or a copper-magnesium-aluminum alloy.

The first conductive layer may include a protrusion portion protruding more than the side surface of the second conductive layer in the direction parallel to the substrate.

The touch electrode may further include a third conductive layer above the second conductive layer and the metal oxide layer, and including a lower surface facing the second conductive layer and the metal oxide layer and forming an undercut.

The lower surface of the third conductive layer may include a first portion contacting the second conductive layer, a second portion contacting the metal oxide layer, and a third portion contacting the touch protection layer.

The second portion may be positioned between the first portion and the third portion.

The third conductive layer may include a molybdenum-titanium-nickel alloy (MTD alloy).

The metal oxide layer may contact a side surface of the first conductive layer.

The metal oxide layer might not contact a side surface of the first conductive layer.

A surface of the metal oxide layer facing the emission area may include an uneven surface.

The metal oxide layer may expose the second conductive layer, and may entirely surround the second conductive layer in plan view.

The metal oxide layer may have a mesh shape defining openings in plan view.

According to one or more embodiments of the present disclosure, a method of fabricating a display device includes forming a first conductive material layer above a substrate including an emission area and a non-emission area, forming a second conductive material layer above the first conductive material layer, forming photoresists above the second conductive material layer and overlapping the non-emission area, performing a first etching process to form a second conductive layer, forming photoresists above the second conductive layer and overlapping the non-emission area, performing a second etching process to form a first conductive layer, and performing oxygen plasma treatment to form a metal oxide layer on a side surface of the first conductive layer and on a side surface of the second conductive layer.

The first etching process may include a wet etching process, wherein the second etching process includes a dry etching process.

The first conductive layer may include a protrusion portion protruding more than the side surface of the second conductive layer.

The first conductive layer and the second conductive layer bay include copper, wherein the metal oxide layer includes copper oxide.

A display device and a method of fabricating the same according to one or more embodiments may reduce side surface reflected light of a touch line by including a metal oxide layer having low light reflectivity on a side surface of the touch line. Accordingly, a reliability defect that a partial area of the display device according to one or more embodiments is viewed to be reddish from the outside of the display device may be solved.

The aspects of the present disclosure are not limited to the aforementioned effects, and various other aspects are included in the present specification.

### BRIEF DESCRIPTION OF THE DRAWINGS

The above and other aspects of the present disclosure will become more apparent by describing in detail embodiments thereof with reference to the attached drawings, in which:

FIG. 1 is a schematic perspective view of an electronic device according to one or more embodiments;

FIG. 2 is a perspective view illustrating a display device included in the electronic device according to one or more embodiments;

FIG. 3 is a schematic cross-sectional view of the display device of FIG. 2;

FIG. 4 is a schematic plan view illustrating a display layer in FIG. 3;

FIG. 5 is a schematic plan view illustrating a touch sensor layer in FIG. 3;

FIG. 6 is an enlarged plan view of area ‘A’ in FIG. 5;

FIG. 7 is a schematic cross-sectional view of the display device taken along the line X1-X1′ in FIG. 6;

FIG. 8 is an enlarged cross-sectional view of area ‘C’ in FIG. 7;

FIG. 9 is a plan view illustrating an arrangement of a second conductive layer and a metal oxide layer in FIG. 8;

FIG. 10 is an enlarged cross-sectional view of area ‘E’ in FIG. 7;

FIG. 11 is an enlarged cross-sectional view of area ‘C’ in FIG. 7 according to one or more other embodiments;

FIGS. 12 to 15 are views illustrating fabricating processes of a second touch electrode included in the display device of FIG. 8;

FIG. 16 is an enlarged cross-sectional view of area ‘C’ in FIG. 7 according to still one or more other embodiments;

FIG. 17 is an enlarged cross-sectional view of area ‘C’ in FIG. 7 according to still one or more other embodiments; and

FIGS. 18 to 22 are views illustrating fabricating processes of a second touch electrode included in a display device of FIG. 17.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

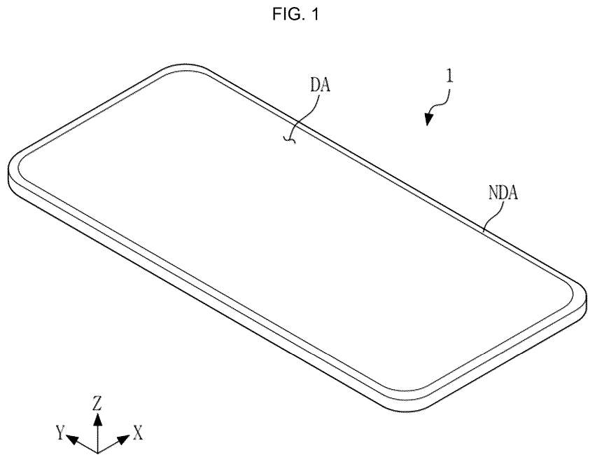

FIG. 1 is a schematic perspective view of an electronic device 1 according to one or more embodiments.

Referring to FIG. 1, the electronic device 1 displays a moving image or a still image. The electronic device 1 may refer to all electronic devices that provide display screens. For example, televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens, may be included in the electronic device 1.

In FIG. 1, a first direction (X-axis direction), a second direction (Y-axis direction), and a third direction (Z-axis direction) are defined. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a transverse direction in the drawings, the second direction (Y-axis direction) refers to a longitudinal direction in the drawings, and the third direction (Z-axis direction) refers to an upward and downward direction (i.e., a thickness direction) in the drawings. In the following specification, unless otherwise specified, the term “direction” may refer to both directions toward both sides extending along the direction. In addition, when both “directions” extending to both sides need to be distinguished from each other, one side will be referred to as “one side in the direction” and the other side will be referred to as “the other side in the direction.” In FIG. 1, a direction to which an arrow indicating a direction is directed will be referred to as one side, and a direction opposite to such a direction will be referred to as the other side.

Hereinafter, for convenience of explanation, in referring to surfaces of the electronic device 1 or respective members of the electronic device 1, one surface facing one side in a direction in which an image is displayed (the third direction/Z-axis direction) will be referred to as an upper surface, and a surface opposite to the one surface will be referred to as the other surface/lower surface. However, the present disclosure is not limited thereto, and the upper and lower surfaces of the member may be respectively referred to as a front surface and a rear surface, or as a first surface and a second surface. In addition, in describing relative positions of the respective members of the electronic device 1, one side in the third direction (Z-axis direction) may be referred to as an upper portion, and the other side in the third direction (Z-axis direction) may be referred to as a lower portion.

A shape of the electronic device 1 may be variously modified. For example, the electronic device 1 may have a shape, such as a rectangular shape with a width that is greater than a length, a rectangular shape with a length that is greater than a width, a square shape, a quadrangular shape with rounded corners (vertices), other polygonal shapes, or a circular shape.

The electronic device 1 may include a display area DA and a non-display area NDA. The display area DA is an area in which a screen may be displayed, and the non-display area NDA is an area in which the screen is not displayed. The display area DA may also be referred to as an active area, and the non-display area NDA may also be referred to as a non-active area. The display area DA may occupy substantially the center of the electronic device 1.

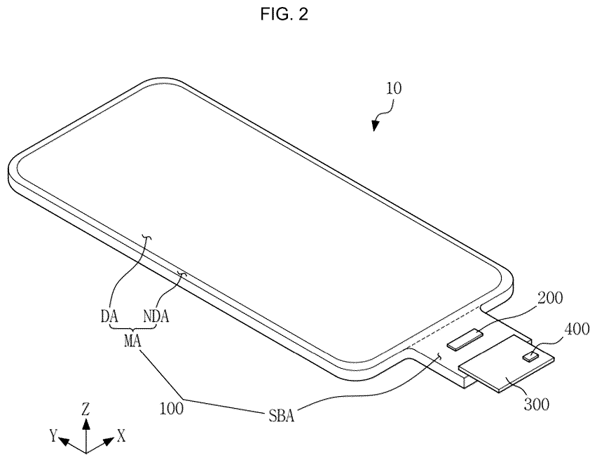

FIG. 2 is a perspective view illustrating a display device 10 included in the electronic device 1 according to one or more embodiments.

Referring to FIG. 2, the electronic device 1 according to one or more embodiments may include a display device 10. The display device 10 may provide a screen displayed on the electronic device 1. Examples of the display device 10 may include an inorganic light-emitting diode display device, an organic light-emitting display device, a quantum dot light-emitting display device, a plasma display panel, a field emission display, and the like. Hereinafter, a case where an organic light-emitting diode display device is applied as an example of the display device will be described by way of example, but the present disclosure is not limited thereto, and the same technical spirit may be applied to other display devices if applicable.

The display device 10 may have a shape similar to that of the electronic device 1 in plan view. For example, the display device 10 may have a rectangular shape in plan view, and having short sides in the first direction (X-axis direction) and long sides in the second direction (Y-axis direction). A corner where the short side in the first direction (X-axis direction) and the long side in the second direction (Y-axis direction) meet may be rounded with a curvature, but is not limited thereto, and may also be right-angled. The shape of the display device 10 in plan view is not limited to the rectangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA. The main area MA may include a display area DA including pixels displaying an image and a non-display area NDA located around the display area DA.

The display area DA may emit light from a plurality of emission areas or a plurality of opening areas to be described later. For example, the display area DA may include pixel circuits including switching elements, a pixel-defining film defining the emission areas or the opening areas, and self-light-emitting elements.

The non-display area NDA may be an area outside the display area DA. The non-display area NDA may be defined as an edge area of the main area MA of the display panel 100. The non-display area NDA may include a line driver for supplying signals to the display area DA and lines connecting the display driver 200 and the display area DA to each other.

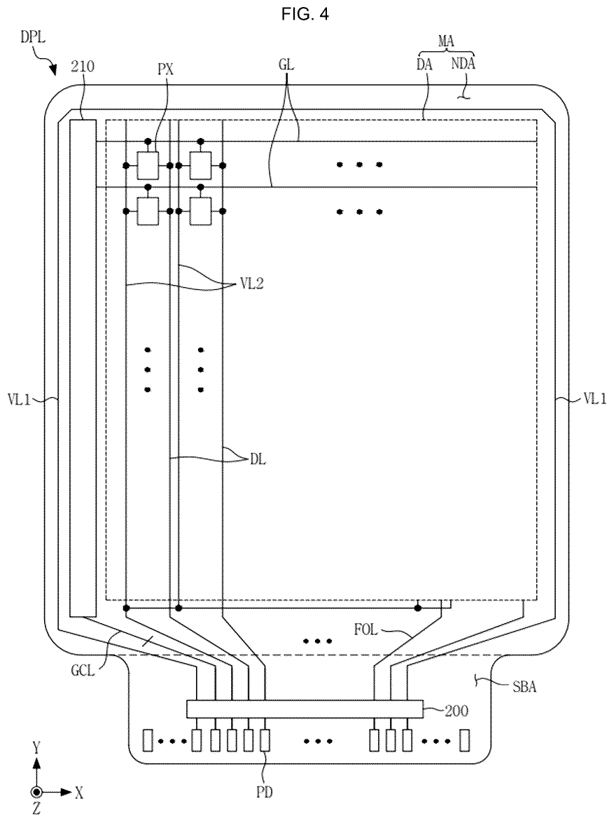

The sub-area SBA may be an area extending from one side of the main area MA. The sub-area SBA may include a flexible material that may be bent, folded, and rolled. For example, when the sub-area SBA is bent, the sub-area SBA may overlap the main area MA in the thickness direction (e.g., the third direction (Z-axis direction)). The sub-area SBA may include the display driver 200 and display pads PD (see FIG. 4) connected to the circuit board 300. In one or more other embodiments, the sub-area SBA may be omitted, and the display driver 200 and the display pads may be positioned in the non-display area NDA.

The display driver 200 may output signals and voltages for driving the display panel 100. The display driver 200 may supply data voltages to data lines DL (see FIG. 4) to be described later. In addition, the display driver 200 may supply source voltages to power lines ‘VL1 and VL2’ (see FIG. 4), and may supply a gate control signal to a gate driver 210 (see FIG. 4). The display driver 200 may be formed as an integrated circuit (IC) and mounted on the display panel 100 in a chip-on-glass (COG) manner, a chip-on-plastic (COP) manner, or an ultrasonic bonding manner. As an example, the display driver 200 may be located in the sub-area SBA, and may overlap the main area MA in the thickness direction by bending of the sub-area SBA. As another example, the display driver 200 may be mounted on the circuit board 300.

The circuit board 300 may be attached onto the display pads of the display panel 100 using an anisotropic conductive film (ACF). The circuit board 300 may be electrically connected to the display pads. The circuit board 300 may be a flexible printed circuit board, a printed circuit board, or a flexible film, such as a chip on film.

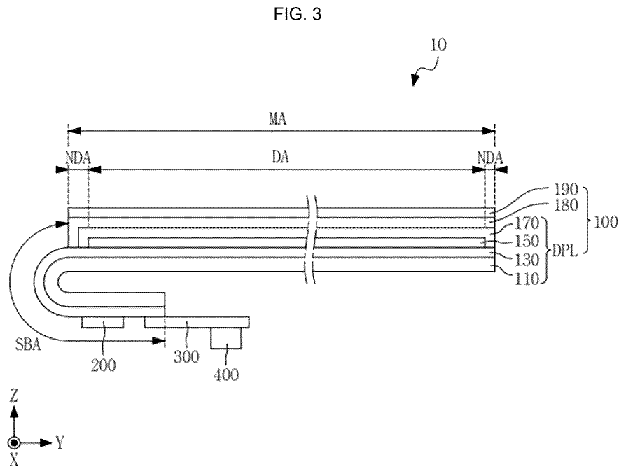

The touch driver 400 may be mounted on the circuit board 300. The touch driving circuit 400 may be connected to a touch sensor layer 180 (see FIG. 3) of the display panel 100.

FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate that may be bent, folded, and rolled. For example, the substrate 110 may include a polymer resin, such as polyimide (PI), but is not limited thereto. In one or more other embodiments, the substrate 110 may include a glass material or a metal material.

The thin film transistor layer 130 may be located on the substrate 110 (as used herein, “located on” may mean “above”). The thin film transistor layer 130 may be located in the display area DA, the non-display area NDA, and the sub-area SBA. The thin film transistor layer 130 may include a plurality of thin film transistors of pixels and a plurality of lines.

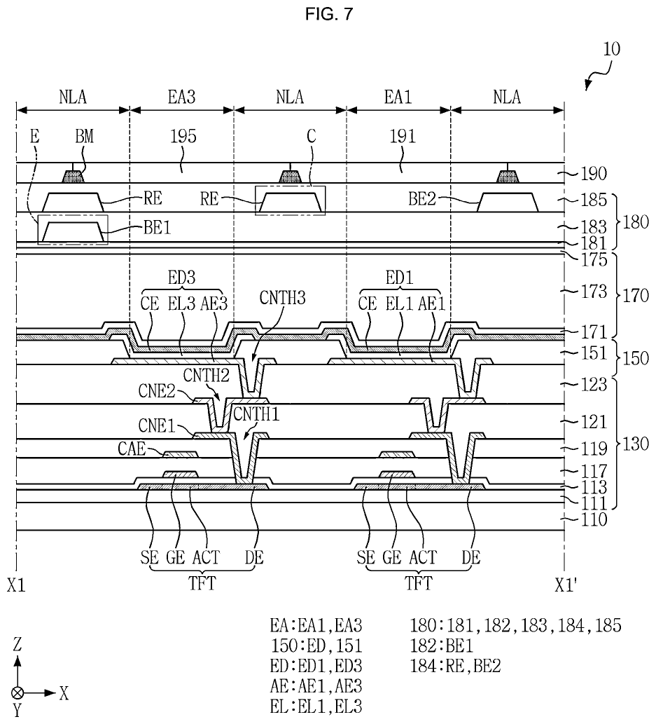

The display element layer 150 may be located on the thin film transistor layer 130. The display element layer 150 may be positioned to overlap the display area DA. The display element layer 150 may include a plurality of light-emitting elements ED (see FIG. 7) and a pixel-defining layer 151 (see FIG. 7). As an example, the light-emitting element according to one or more embodiments may include at least one of an organic light-emitting diode (LED) including an organic light-emitting layer, a quantum dot LED including a quantum dot light-emitting layer, an inorganic LED including an inorganic semiconductor, or a micro LED, but is not limited thereto.

The thin film encapsulation layer 170 may be positioned on the display element layer 150. The thin film encapsulation layer 170 may be positioned to overlap the display area DA and the non-display area NDA. The thin film encapsulation layer 170 may cover an upper surface and side surfaces of the display element layer 150, and may protect the display element layer 150 from external oxygen and moisture. The thin film encapsulation layer 170 may include at least one inorganic film and at least one organic film for encapsulating the display element layer 150.

The touch sensor layer 180 may be located on the thin film encapsulation layer 170. The touch sensor layer 180 may be positioned to overlap the display area DA and the non-display area NDA. The touch sensor layer 180 may sense a user's touch in a mutual capacitance manner or a self-capacitance manner.

The color filter layer 190 may be located on the touch sensor layer 180. The color filter layer 190 may be positioned to overlap the display area DA and the non-display area NDA. The color filter layer 190 may absorb some of the light introduced from the outside of the display device 10 to reduce reflected light by external light. Accordingly, the color filter layer 190 may reduce or prevent distortion of colors due to external light reflection.

Because the color filter layer 190 is directly located on the touch sensor layer 180, the display device 10 may not require a separate substrate for the color filter layer 190. Accordingly, a thickness of the display device 10 may be relatively small. In addition, the color filter layer 190 may also be omitted according to embodiments.

As illustrated in FIG. 3, a portion of the display layer DPL overlapping the sub-area SBA may be bent. When a portion of the display layer DPL is bent, the display driver 200, the circuit board 300, and the touch driver 400 may overlap the main area MA in the third direction (Z-axis direction).

FIG. 4 is a schematic plan view illustrating a display layer of FIG. 3.

Referring to FIG. 4, the display layer DPL included in one or more embodiments may include a plurality of pixels PX, a plurality of gate lines GL, a plurality of data lines DL, and a plurality of second power lines VL2 in a portion overlapping the display area DA of the main area MA.

Each of the plurality of pixels PX may be defined as a minimum unit emitting light. Each of the plurality of pixels PX may be of a respective one of first to third emission areas EA1, EA2, and EA3 to be described later.

The plurality of gate lines GL may supply gate signals received from the gate driver 210 to the plurality of pixels PX. The plurality of gate lines GL may extend in the first direction (X-axis direction), and may be spaced apart from each other in the second direction (Y-axis direction) crossing the first direction (X-axis direction).

The plurality of data lines DL may supply data voltages received from the display driver 200 to the plurality of pixels PX. The plurality of data lines DL may extend in the second direction (Y-axis direction), and may be spaced apart from each other in the first direction (X-axis direction).

The plurality of second power lines VL2 may supply a source voltage received from the display driver 200 to the plurality of pixels PX. Here, the source voltage may be at least one of a driving voltage, an initialization voltage, or a reference voltage. The plurality of second power lines VL2 may extend in the second direction (Y-axis direction), and may be spaced apart from each other in the first direction (X-axis direction).

The display layer DPL included in one or more embodiments may include a first power line VL1, the gate driver 210, a plurality of fan-out lines FOL, and a gate control line GCL in a portion overlapping the non-display area NDA of the main area MA.

The gate driver 210 may generate a plurality of gate signals based on a gate control signal, and may sequentially supply the plurality of gate signals to the plurality of gate lines GL according to a set order.

The first power line VL1 may be located in the non-display area NDA so as to surround the display area DA. The first power line VL1 may supply a source voltage received from the display driver 200 to the plurality of pixels PX. In addition, the first power line VL1 may be electrically connected to various lines positioned in the display area DA.

The plurality of fan-out lines FOL may extend from the display driver 200 to the display area DA. The fan-out lines FOL may supply the data voltages received from the display driver 200 to the plurality of data lines DL.

The gate control line GCL may extend from the display driver 200 to the gate driver 210. The gate control line GCL may supply the gate control signal received from the display driver 200 to the gate driver 210. It has been illustrated in FIG. 4 that the gate driver 210 is located only in a non-display area NDA located on the left side of the display area DA, but the present disclosure is not limited thereto. In one or more other embodiments, the display device 10 may include a plurality of gate drivers 210 respectively located on the left side and the right side of the display area DA.

The display layer DPL included in one or more embodiments may include the display driver 200 and a plurality of display pads PD in a portion overlapping the sub-area SBA.

The display driver 200 may output signals and voltages for driving the plurality of pixels PX to the plurality of fan-out lines FOL. The display driver 200 may supply the data voltages to the data lines DL through the plurality of fan-out lines FOL. Therefore, the data voltages may be supplied to the plurality of pixels PX, and may control luminance of the plurality of pixels PX. In addition, the display driver 200 may supply the gate control signals to the gate driver 210 through the gate control lines GCL.

The plurality of display pads PD may be connected to a graphic system through the circuit board 300. The plurality of display pads PD may be connected to the circuit board 300 to receive digital video data, and may supply the digital video data to the display driver 200.

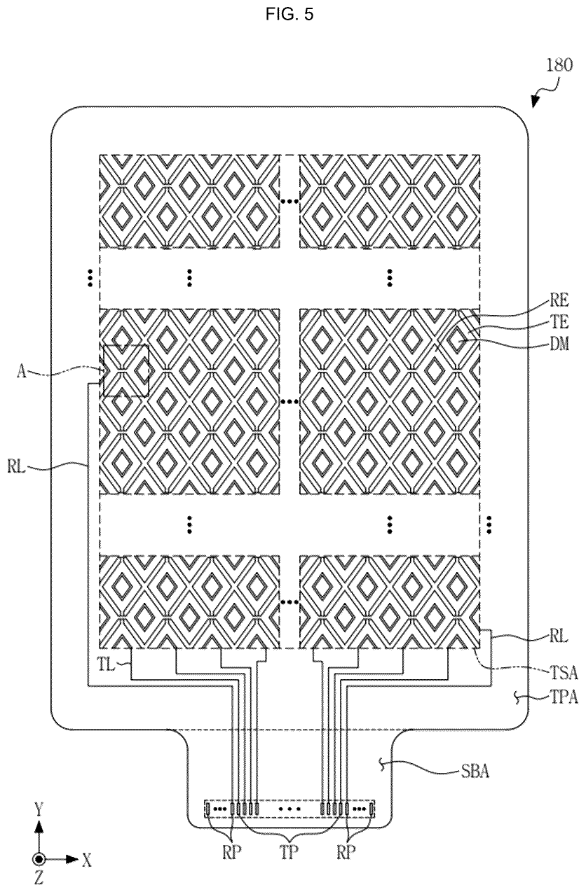

FIG. 5 is a schematic plan view illustrating a touch sensor layer of FIG. 4.

Referring to FIG. 5, the touch sensor layer 180 may include a touch-sensing area TSA for sensing a user's touch and a touch peripheral area TPA located around the touch-sensing area TSA. The touch-sensing area TSA may overlap the display area DA of FIG. 4, and the touch peripheral area TPA may overlap the non-display area NDA of FIG. 4.

In some embodiments, the touch sensor layer 180 may include a plurality of driving electrodes TE, a plurality of sensing electrodes RE, and a plurality of dummy electrodes DM in a portion overlapping the touch-sensing area TSA, and may include a plurality of driving lines TL and a plurality of sensing lines RL in a portion overlapping the touch peripheral area TPA. In addition, the touch sensor layer 180 may include a plurality of driving pads TP and a plurality of sensing pads RP in a portion overlapping the sub-area SBA.

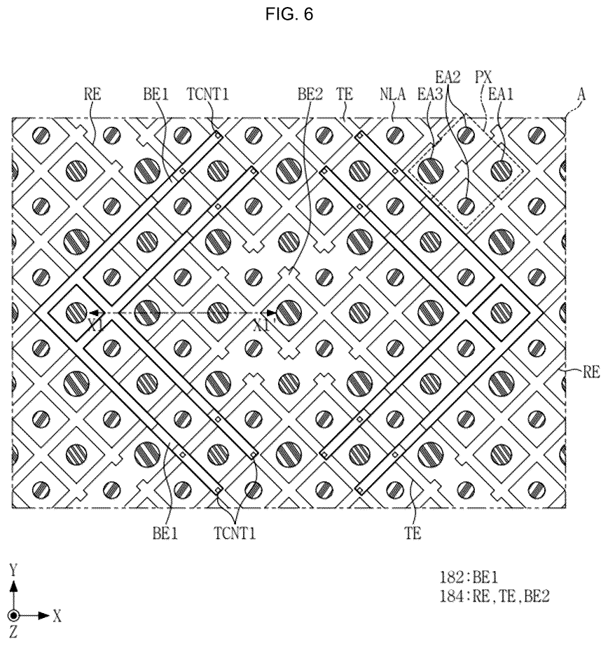

The plurality of sensing electrodes RE may extend in the first direction (X-axis direction). As an example, the plurality of sensing electrodes RE may be located from the left of the touch-sensing area TSA to the right of the touch-sensing area TSA. The plurality of sensing electrodes RE may be electrically disconnected from each other, and respective portions of the sensing electrodes RE may be connected to each other through second connection electrodes BE2 (see FIG. 6) to be described later. Each of the plurality of sensing electrodes RE may be connected to a corresponding sensing line RL on one side and the other side of the touch-sensing area TSA in the first direction (X-axis direction).

The plurality of driving electrodes TE may extend in the second direction (Y-axis direction). As an example, the plurality of driving electrodes TE may be located from the lower side of the touch-sensing area TSA to the upper side of the touch-sensing area TSA. The plurality of driving electrodes TE may be electrically disconnected from each other. Portions of the driving electrodes TE neighboring each other in the second direction (Y-axis direction) may be connected through first connection electrodes BE1 (see FIG. 6). Each of the plurality of driving electrodes TE may be connected to a corresponding driving line TL on one side (direction in which the plurality of driving pads TP and the plurality of sensing pads RP are positioned) of the touch-sensing area TSA in the second direction (Y-axis direction).

Each of the dummy electrodes DM may be surrounded by a driving electrode TE or a sensing electrode RE. Each of the plurality of dummy electrodes DM may be electrically disconnected from the driving electrode TE or the sensing electrode RE. The dummy electrode DM may be spaced apart from the driving electrode TE or the sensing electrode RE, and may be electrically floated from the driving electrode TE or the sensing electrode RE.

It has been illustrated in FIG. 5 that each of the plurality of driving electrodes TE, the plurality of sensing electrodes RE, and the plurality of dummy electrodes DM has a rhombic shape in plan view, but the present disclosure is not limited thereto. For example, each of each of the plurality of driving electrodes TE, the plurality of sensing electrodes RE, and the plurality of dummy electrodes DM may have a quadrangular shape other than the rhombic shape, a polygonal shape other than the quadrangular shape, a circular shape, or an elliptical shape in plan view.

The plurality of driving pads TP and the plurality of sensing pads RP may be located in the sub-area SBA. The plurality of driving pads TP and the plurality of sensing pads RP may be electrically connected to the plurality of display pads PD through conductive adhesive members, such as anisotropic conductive films.

FIG. 6 is an enlarged plan view of area ‘A’ in FIG. 5. FIG. 6 is a plan view illustrating a schematic arrangement of the display area DA included in the display device 10.

Referring to FIG. 6, the touch sensor layer 180 (see FIG. 3) may include a first touch electrode 182 and a second touch electrode 184. The first touch electrode 182 may include the first connection electrode BE1, and the second touch electrode 184 may include the driving electrode TE, the sensing electrode RE, and the second connection electrode BE2. The first touch electrode 182 and the second touch electrode 184 may be positioned at different layers in a cross section. In other words, the first connection electrode BE1 included in the first touch electrode 182 may be positioned at a different layer from the second connection electrode BE2, the driving electrode TE, and the sensing electrode RE included in the second touch electrode 184.

The first touch electrode 182 and the second touch electrode 184 may be formed in a mesh shape. In general, when the touch sensor layer 180 is formed directly on the thin film encapsulation layer 170, relatively large parasitic capacitance may be formed between a common electrode CE (see FIG. 7) and the first and second touch electrodes 182 and 184. Therefore, to reduce such parasitic capacitance, the first touch electrode 182 and the second touch electrode 184 may be formed as electrodes having a mesh shape. Therefore, the first touch electrode 182 and the second touch electrode 184 may not overlap a plurality of emission areas EA1, EA2, and EA3. That is, it is possible to reduce or prevent the likelihood of a plurality of electrodes included in the touch sensor layer 180 blocking light emitted from the plurality of emission areas EA1, EA2, and EA3 to reduce luminance of the light.

The first connection electrode BE1 included in the first touch electrode 182 may electrically connect neighboring driving electrodes TE to each other. However, as described above, the first connection electrode BE1 and the driving electrode TE may be located at different layers in a cross section. Accordingly, one side of the first connection electrode BE1 may be connected to any one of the driving electrodes TE adjacent to each other in the second direction (Y-axis direction) through touch contact holes TCNT1. Similarly, the other side of the connection electrode BE1 may be connected to the other of the driving electrodes TE adjacent to each other in the second direction (Y-axis direction) through touch contact holes TCNT1. Therefore, the plurality of driving electrodes TE adjacent to each other in the second direction (Y-axis direction) may be electrically connected to each other by the first connection electrode BE1, and the plurality of driving electrodes TE and the plurality of sensing electrodes RE neighboring each other may be electrically disconnected from each other at portions where they intersect each other.

In addition, sensing electrodes RE adjacent to each other in the first direction (X-axis direction) may be respectively electrically connected to each other by a plurality of second connection electrodes BE2. The second connection electrodes BE2 are located at the same layer as the plurality of sensing electrodes RE, and may thus be directly electrically connected to the plurality of sensing electrodes RE without touch contact holes.

As illustrated in FIG. 6, the emission areas EA1, EA2, and EA3 may be defined between the first touch electrode 182 and the second touch electrode 184. The respective emission areas EA1, EA2, and EA3 may include first emission areas EA1 for emitting light of a first color, second emission areas EA2 for emitting light of a second color, and third emission areas EA3 for emitting light of a third color. The first emission area EA1 and the third emission area EA3 may neighbor to each other in the first direction (X-axis direction), and a plurality of second emission areas EA2 may neighbor to each other in the second direction (Y-axis direction), but the present disclosure is not limited thereto.

In some embodiments, the pixel PX may include at least one first emission area EA1, at least two second emission areas EA2, and at least one third emission area EA3. As an example, the first color may be red, the second color may be green, and the third color may be blue. The pixel PX may be a minimum unit for emitting white light.

A non-emission area NLA may be positioned to surround the respective emission areas EA1, EA2, and EA3. A pixel-defining layer 151 to be described later, the first touch electrode 182, the second touch electrode 184, and a light-blocking layer BM may overlap the non-emission area NLA.

FIG. 7 is a schematic cross-sectional view of the display device 10 taken along the line X1-X1′ in FIG. 6. A cross-sectional structure of the display device 10 will be described with reference to FIG. 7. The substrate 110 has been described above, and a detailed description thereof is thus omitted.

The thin film transistor layer 130 may include a buffer layer 111, thin film transistors TFT, a gate-insulating layer 113, a first interlayer insulating layer 117, a second interlayer insulating layer 119, first connection electrodes CNE1, a first via layer 121, second connection electrodes CNE2, and a second via layer 123.

The buffer layer 111 may be positioned on the substrate 110. The buffer layer 111 may include an inorganic film capable of reducing or preventing permeation of air or moisture. For example, the buffer layer 111 may include a plurality of inorganic films that are alternately stacked. As an example, the buffer layer 111 may be formed as multiple films in which one or more inorganic films of a silicon nitride layer, a silicon oxynitride layer, a silicon oxide layer, a titanium oxide layer, and an aluminum oxide layer are alternately stacked.

The thin film transistors TFT may be positioned on the buffer layer 111. The thin film transistor TFT may include an active layer ACT, a gate electrode GE, a source electrode SE, and a drain electrode DE. The active layer ACT of the thin film transistor TFT includes polycrystalline silicon, single crystal silicon, low-temperature polycrystalline silicon, amorphous silicon, or an oxide semiconductor. The active layer ACT overlapping the gate electrode GE in the third direction (Z-axis direction), which is a thickness direction of the substrate 110, may be defined as a channel region. The source electrode SE and the drain electrode DE are regions that do not overlap the gate electrode GE in the third direction (Z-axis direction), and may have conductivity by doping a silicon semiconductor or an oxide semiconductor with ions or impurities.

The gate-insulating layer 113 may be positioned on the thin film transistors TFT. The gate-insulating layer 113 may cover the thin film transistors TFT and the buffer layer 111, and may insulate the active layer ACT and the gate electrode GE from each other. The gate-insulating layer 113 may be located at substantially the same thickness along a profile of the thin film transistor TFT. The gate-insulating layer 113 may include first contact holes CNTH1 through which the first connection electrodes CNE1 penetrate.

The gate-insulating layer 113 may include an inorganic insulating material, and may be formed as a plurality of layers. As an example, the gate-insulating layer 113 may be made of an inorganic material, such as a silicon nitride layer, a silicon oxynitride layer, a silicon oxide layer, a titanium oxide layer, and an aluminum oxide layer.

The gate electrode GE may be located on the gate-insulating layer 113. The gate electrode GE may overlap the active layer ACT with the gate-insulating layer 113 interposed therebetween. The gate electrode GE may include a metal. As an example, the gate electrode GE may include one or more metals selected from molybdenum (Mo), aluminum (AI), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), or copper (Cu).

The first interlayer insulating layer 117 may be located on the gate electrodes GE. The first interlayer insulating layer 117 may include an inorganic insulating material, and may be formed as a plurality of layers. As an example, the first interlayer insulating layer 117 may be formed as a silicon nitride layer, a silicon oxynitride layer, a silicon oxide layer, a titanium oxide layer, or an aluminum oxide layer. The first interlayer insulating layer 117 may include first contact holes CNTH1 through which the first connection electrodes CNE1 penetrate.

Capacitor electrodes CAE may be located on the first interlayer insulating layer 117. The capacitor electrode CAE may overlap the gate electrode GE of the thin film transistor T in the third direction (Z-axis direction). Because the first interlayer insulating layer 117 has a dielectric constant (e.g., predetermined dielectric constant), a capacitor may be formed by the capacitor electrode CAE, the gate electrode GE, and the first interlayer insulating layer 117 located between the capacitor electrode CAE and the gate electrode GE. The capacitor electrode CAE may include a metal. As an example, the capacitor electrode CAE may include one or more metals selected from molybdenum (Mo), aluminum (AI), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), or copper (Cu).

The second interlayer insulating layer 119 may be positioned on the first interlayer insulating layer 117 and the capacitor electrodes CAE. The second interlayer insulating layer 119 may include an inorganic insulating material, and may be formed as a plurality of layers. As an example, the second interlayer insulating layer 119 may be formed as a silicon nitride layer, a silicon oxynitride layer, a silicon oxide layer, a titanium oxide layer, or an aluminum oxide layer. The second interlayer insulating layer 119 may include first contact holes CNTH1 through which the first connection electrodes CNE1 penetrate.

The first connection electrodes CNE1 may be located on the second interlayer insulating layer 119. The first connection electrode CNE1 may electrically connect the drain electrode DE of the thin film transistor TFT and the second connection electrode CNE2 to each other. The first connection electrode CNE1 may be inserted into the first contact holes CNTH1 formed in the first interlayer insulating layer 117, the second interlayer insulating layer 119, and the gate-insulating layer 113 to contact the drain electrode DE of the thin film transistor TFT.

The first via layer 121 may cover the first connection electrodes CNE1 and the second interlayer insulating layer 119. The first via layer 121 may protect the thin film transistors TFT. The first via layer 121 may include an organic material. As an example, the first via layer 121 may include an organic material, such as an acrylic resin, an epoxy resin, a phenolic resin, a polyamide resin, or a polyimide resin. The first via layer 121 may include second contact holes CNTH2 through which the second connection electrodes CNE2 penetrate.

The second connection electrodes CNE2 may be located on the first via layer 121. The second connection electrode CNE2 may electrically connect the first connection electrode CNE1 and a pixel electrode AE to each other. The second connection electrode CNE2 may contact the first connection electrode CNE1 through the second contact hole CNTH2 formed in the first via layer 121.

The second via layer 123 may be positioned on the second connection electrodes CNE2 and the first via layer 121. The second via layer 123 may cover the second connection electrodes CNE2 and the first via layer 121. The second via layer 123 may include an organic material. As an example, the second via layer 123 may include an organic material, such as an acrylic resin, an epoxy resin, a phenolic resin, a polyamide resin, or a polyimide resin. The second via layer 123 may include third contact holes CNTH3 through which pixel electrodes AE of light-emitting elements ED penetrate.

The display element layer 150 may be located on the thin film transistor layer 130. The display element layer 150 may include light-emitting elements ED and a pixel-defining layer 151.

The light-emitting elements ED may include a first light-emitting element ED1, a second light-emitting element ED2, and a third light-emitting element ED3 respectively overlapping the first to third emission areas EA1, EA2, and EA3. For convenience of explanation, the first light-emitting element ED1 and the third light-emitting element ED3 have been illustrated and described in FIG. 7, but the second light-emitting element ED2 may also have the same structure and features as the first light-emitting element ED1 and the third light-emitting element ED3.

For example, the first light-emitting element ED1 may overlap the first emission area EA1, the second light-emitting element ED2 may overlap the second emission area EA2, and the third light-emitting element ED3 may overlap the third emission area EA3. In addition, the first light-emitting element ED1 may include a first pixel electrode AE1, a first light-emitting layer EL1, and a common electrode CE, the second light-emitting element ED2 may include a second pixel electrode AE2, a second light-emitting layer EL2, and a common electrode CE, and the third light-emitting element ED3 may include a third pixel electrode AE3, a third light-emitting layer EL3, and a common electrode CE.

The pixel electrodes AE may be located on the second via layer 123 in portions overlapping the respective emission areas EA. As an example, the pixel electrodes AE may include the first pixel electrode AE1 overlapping the first emission area EA1, the second pixel electrode AE2 overlapping the second emission area EA2, and the third pixel electrode AE3 overlapping the third emission area EA3. For convenience of explanation, the first pixel electrode AE1 and the third pixel electrode AE3 have been illustrated and described in FIG. 7, but the second pixel electrode AE2 may also have the same structure and features as the first pixel electrode AE1 and the third pixel electrode AE3.

The pixel electrode AE may be electrically connected to the drain electrode DE of the thin film transistor TFT through the first connection electrode CNE1 and the second connection electrode CNE2. The pixel electrode AE may be made of a metal having high electrical conductivity. As an example, the pixel electrode AE may have a stacked film structure in which a layer made of a material having a high work function, such as indium tin oxide (ITO), indium zinc oxide (IZO), zinc oxide (ZnO), or indium oxide (In₂O₃), and a layer made of a reflective material, such as silver (Ag), magnesium (Mg), aluminum (AI), platinum (Pt), lead (Pb), palladium (Pd), gold (Au), nickel (Ni), neodymium (Nd), iridium (Ir), chromium (Cr), lithium (Li), calcium (Ca), or mixtures thereof, are stacked. The layer made of the material having the high work function may be located at a layer above the layer made of the reflective material, and thus may be located close to the light-emitting layers EL1, EL2, and EL3. As an example, the pixel electrode AE may have a multilayer structure of ITO/Mg, ITO/MgF, ITO/Ag, and ITO/Ag/ITO, but is not limited thereto.

The pixel-defining layer 151 may define the emission areas EA and the non-

emission area NLA. The pixel-defining layer 151 may expose portions of the pixel electrodes AE on the second via layer 123, and may cover edges of the pixel electrodes AE. The pixel-defining layer 151 may be located within the third contact holes CNTH3. That is, the third contact holes CNTH3 may be filled with the pixel-defining layer 151.

The pixel-defining layer 151 may include an organic material. As an example, the pixel-defining layer 151 may include an organic material, such as an acrylic resin, an epoxy resin, a phenolic resin, a polyamide resin, or a polyimide resin.

Light-emitting layers EL may be positioned on the pixel electrodes AE in portions overlapping the first to third emission areas EA1, EA2, and EA3. As an example, the light-emitting layers EL may include the first light-emitting layer EL1 overlapping the first emission area EA1, the second light-emitting layer EL2 overlapping the second emission area EA2, and the third light-emitting layer EL3 overlapping the third emission area EA3. For convenience of explanation, the first light-emitting layer EL1 and the third light-emitting layer EL3 have been illustrated and described in FIG. 7, but the second light-emitting layer EL2 may also have the same structure and features as the first light-emitting layer EL1 and the third light-emitting layer EL3.

The light-emitting layer EL may include an organic material to emit light of a color (e.g., predetermined color). For example, the light-emitting layer EL may include a hole-transporting layer, an organic material layer, and an electron-transporting layer. The organic material layer may include a host and a dopant. The organic material layer may include a material for emitting light (e.g., predetermined light), and may be formed using a phosphorescent material or a fluorescent material.

The common electrode CE may be located on the light-emitting layers EL and the pixel-defining layer 151. The common electrode CE may be a common layer entirely formed on the first to third light-emitting layers EL1, EL2, and EL3 and the pixel-defining layer 151. The common electrode CE may include a transparent conductive material to emit the light generated from the light-emitting layer EL. The common electrode CE may receive a common voltage or a low potential voltage. When the pixel electrode AE receives a voltage corresponding to a data voltage while the common electrode CE receives the low potential voltage, a potential difference is formed between the pixel electrode AE and the common electrode CE, such that the light-emitting layer EL may emit the light.

The common electrode CE may be made of a transparent conductive material (TCO), such as ITO or IZO capable of transmitting light therethrough or a semi-transmissive conductive material, such as magnesium (Mg), silver (Ag), or an alloy of magnesium (Mg) and silver (Ag). When the common electrode CE is made of the semi-transmissive conductive material, emission efficiency may be increased by a micro cavity.

The thin film encapsulation layer 170 may be located on the display element layer 150. The thin film encapsulation layer 170 may include at least one inorganic film to reduce or prevent permeation of oxygen or moisture into the display element layer 150. In addition, the thin film encapsulation layer 170 may include at least one organic film to protect the display element layer 150 from foreign substances, such as dust. The thin film encapsulation layer 170 may include a first encapsulation layer 171, a second encapsulation layer 173, and a third encapsulation layer 175. The first encapsulation layer 171 may be located on the common electrode CE, the second encapsulation layer 173 may be located on the first encapsulation layer 171, and the third encapsulation layer 175 may be located on the second encapsulation layer 173.

The first encapsulation layer 171 and the third encapsulation layer 175 may be inorganic films. As an example, the first encapsulation layer 171 and the third encapsulation layer 175 may be formed as multiple films in which one or more inorganic films of a silicon nitride layer, a silicon oxynitride layer, a silicon oxide layer, a titanium oxide layer, and an aluminum oxide layer are alternately stacked.

The second encapsulation layer 173 may be an organic film. As an example, the second encapsulation layer 173 may include an organic material, such as an acrylic resin, an epoxy resin, a phenolic resin, a polyamide resin, or a polyimide resin.

The touch sensor layer 180 may be located on the thin film encapsulation layer 170. The touch sensor layer 180 may include a touch buffer layer 181, the first touch electrode 182, a touch-insulating layer 183, the second touch electrode 184, and a touch protection layer 185.

The touch buffer layer 181 may be located on the thin film encapsulation layer 170. The touch buffer layer 181 may include at least one inorganic film. For example, the touch buffer layer 181 may be formed as multiple films in which one or more inorganic films of a silicon nitride layer, a silicon oxynitride layer, a silicon oxide layer, a titanium oxide layer, and an aluminum oxide layer are alternately stacked. The touch buffer layer 181 may be omitted.

The first touch electrode 182 may be located in a portion overlapping the non-emission area NLA, and may be positioned on the touch buffer layer 181. The first touch electrode 182 may include the first connection electrode BE1. As described above, the first connection electrode BE1 may serve to electrically connect neighboring driving electrodes TE to each other. The first touch electrode 182 according to one or more embodiments may have a multilayer structure including copper (Cu). Detailed contents thereof will be described later.

The touch-insulating layer 183 may be located on the touch buffer layer 181 and the first touch electrode 182. The touch-insulating layer 183 may insulate the first touch electrode 182 and the second touch electrode 184 from each other. The touch-insulating layer 183 may be formed as an inorganic film, such as a silicon nitride layer, a silicon oxynitride layer, a silicon oxide layer, a titanium oxide layer, or an aluminum oxide layer.

The second touch electrode 184 may be located in a portion overlapping the non-emission area NLA, and may be positioned on the touch-insulating layer 183. The second touch electrode 184 may include the second connection electrode BE2, the driving electrode TE, and the sensing electrode RE. As described above, the second connection electrode BE2 may serve to electrically connect neighboring sensing electrodes RE to each other. The second touch electrode 184 according to one or more embodiments may have a multilayer structure including copper (Cu). Detailed contents thereof will be described later.

The touch protection layer 185 may be located on the touch-insulating layer 183 and the second touch electrode 184. The touch protection layer 185 may serve to planarize a profile of an underlying structure. The touch protection layer 185 may include at least one of an inorganic film or an organic film. The inorganic film may be a silicon nitride layer, a silicon oxynitride layer, a silicon oxide layer, a titanium oxide layer, or an aluminum oxide layer. The organic film may include an organic material, such as an acrylic resin, an epoxy resin, a phenolic resin, a polyamide resin, or a polyimide resin.

The light-blocking layer BM may be located in portions overlapping the non-emission area NLA, and may be located on the touch sensor layer 180. The light-blocking layer BM may overlap the pixel-defining layer 151, the first touch electrode 182, and the second touch electrode 184. The light-blocking layer BM may reduce or prevent color mixing due to permeation of visible light between the first to third emission areas EA1, EA2, and EA3 to improve a color gamut of the display device 10.

The light-blocking layer BM may include a light-absorbing material. As an example, the light-blocking layer BM may include an inorganic black pigment or an organic black pigment. The inorganic black pigment may be carbon black, and the organic black pigment may include at least one of Lactam Black, Perylene Black, or Aniline Black, but the present disclosure is not limited thereto.

The color filter layer 190 may be located on each of the touch protection layer 185 and the light-blocking layer BM. The color filter layer 190 may include a first color filter 191, a second color filter 193, and a third color filter 195 located to respectively correspond to the first to third emission areas EA1, EA2, and EA3. The first to third color filters 191, 193, and 195 may include colorants, such as dyes or pigments for absorbing light of wavelength bands other than light of a corresponding wavelength band, and may be located to correspond to the colors of the light emitted from the emission areas EA1, EA2, and EA3. For example, the first color filter 191 may be a red color filter overlapping the first emission area EA1 and transmitting only first light, which is red light, therethrough. The second color filter 193 may be a green color filter overlapping the second emission area EA2 and transmitting only second light, which is green light, therethrough, and the third color filter 195 may be a blue color filter overlapping the third emission area EA3 and transmitting only third light, which is blue light, therethrough.

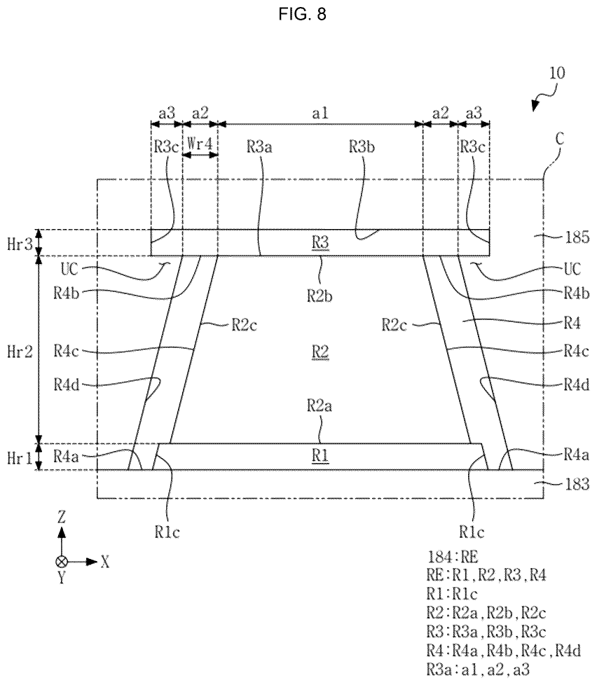

FIG. 8 is an enlarged cross-sectional view of area ‘C’ in FIG. 7;

Referring to FIG. 8, the second touch electrode 184 according to one or more embodiments may include a first conductive layer R1, a second conductive layer R2, and a third conductive layer R3 that are stacked in the third direction (Z-axis direction), and a metal oxide layer R4 located on the second conductive layer R2 (e.g., on sides of the second conductive layer R2) in the first direction (X-axis direction). The sensing electrode RE has been illustrated and then described in FIG. 8, but the second touch electrodes 184 according to one or more embodiments may all have the same structure and features.

The first conductive layer R1 according to one or more embodiments may be positioned on the touch-insulating layer 183. The first conductive layer R1 may have high adhesive strength with the touch-insulating layer 183. For example, the first conductive layer R1 may have high adhesive strength with the inorganic insulating material included in the touch-insulating layer 183.

In some embodiments, the adhesive strength between the first conductive layer R1 and the touch-insulating layer 183 may be higher than the adhesive strength between the touch-insulating layer 183 and each of the second conductive layer R2, the third conductive layer R3, and the metal oxide layer R4.

The first conductive layer R1 may include a conductive metal material. As an example, the first conductive layer R1 may include a copper (Cu)-magnesium (Mg)-aluminum (Al) alloy (Cu—Mg—Al alloy). As an example, in a case where the first conductive layer R1 includes the copper (Cu)-magnesium (Mg)-aluminum (Al) alloy (Cu—Mg—Al alloy), when the total number of atoms in the first conductive layer R1 is defined as 100 at %, the sum of the numbers of atoms of magnesium (Mg) and aluminum (Al) may be about 10 at % or less.

In some embodiments, side surfaces R1c of the first conductive layer R1 may be covered by a metal oxide layer R4 to be described later. Detailed contents thereof will be described later.

The second conductive layer R2 according to one or more embodiments may be located on the first conductive layer R1 so as to contact the first conductive layer R1. The second conductive layer R2 may include a low-resistance metal material. The second conductive layer R2 according to one or more embodiments may include copper (Cu).

In some embodiments, the second conductive layer R2 may include a lower surface R2a, an upper surface R2b, and side surfaces R2c. The lower surface R2a of the second conductive layer R2 may be one surface contacting the first conductive layer R1, and the upper surface R2b of the second conductive layer R2 may be one surface opposing the lower surface R2a, and contacting the third conductive layer R3. In addition, the side surface R2c of the second conductive layer R2 may be one surface connecting the upper surface R2b and the lower surface R2a to each other. The side surface R2c of the second conductive layer R2 may contact the metal oxide layer R4, and may be completely covered by the metal oxide layer R4.

In some embodiments, a height Hr1 of the first conductive layer R1 in the third direction (Z-axis direction) may be less than a height Hr2 of the second conductive layer R2. As an example, the height Hr1 of the first conductive layer R1 may be 100 Å or more and 200 Å or less, and the height Hr2 of the second conductive layer R2 may be 2,500 Å or more and 6,500 Å or less, but the present disclosure is not limited thereto.

The third conductive layer R3 according to one or more embodiments may be located on the second conductive layer R2 so as to contact the second conductive layer R2. The third conductive layer R3 according to one or more embodiments may include a metal material having resistance to oxidation treatment. In other words, the third conductive layer R3 may have oxidation resistance. As an example, the third conductive layer R3 may include a molybdenum (Mo)-titanium (Ti)-nickel (Ni) alloy (MTD alloy). As an example, in a case where the third conductive layer R3 includes the molybdenum (Mo)-titanium (Ti)-nickel (Ni) alloy (MTD alloy), when the total number of atoms in the third conductive layer R3 is defined as 100 at %, the number of atoms of each of molybdenum (Mo), titanium (Ti), and nickel (Ni) may be about 25 at % or more and about 35 at % or less.

In some embodiments, the third conductive layer R3 may include a lower surface R3a, an upper surface R3b, and side surfaces R3c. The lower surface R3a of the third conductive layer R3 may be one surface contacting the second conductive layer R2, and the upper surface R3b of the third conductive layer R3 may be one surface opposing the lower surface R3a, and contacting the touch protection layer 185. The side surface R3c of the third conductive layer R3 may be one surface connecting the upper surface R3b and the lower surface R3a to each other.

In some embodiments, the lower surface R3a of the third conductive layer R3 may include a first portion a1, second portions a2, and third portions a3 corresponding to portions with which the lower surface R3a is in contact. The first portion a1 may be a portion contacting the second conductive layer R2, the second portion a2 may be a portion contacting the metal oxide layer R4, and the third portion a3 may be a portion contacting the touch protection layer 185. The first portion a1 may be positioned between a plurality of second portions a2.

The side surface R3c included in the third conductive layer R3 may protrude more than the side surfaces R2c of the second conductive layer R2 in the first direction (X-axis direction). Accordingly, an undercut UC may be formed between the third conductive layer R3 and the side surface R2c of the second conductive layer R2.

Referring to FIG. 7, a direction in which the side surface R3c of the third conductive layer R3 protrudes may be a direction toward the emission area EA.

In some embodiments, a height Hr3 of the third conductive layer R3 in the third direction (Z-axis direction) may be less than the height Hr2 of the second conductive layer R2. As an example, the height Hr3 of the third conductive layer R3 may be about 100 Å or more and about 200 Å or less, but is not limited thereto.

The metal oxide layer R4 according to one or more embodiments may be located on the side surface R2c of the second conductive layer R2 so as to contact the side surface R2c of the second conductive layer R2, and may entirely cover the side surface R2c of the second conductive layer R2. In addition, the metal oxide layer R4 of the display device 10 may be located on the side surface R1c of the first conductive layer R1 so as to contact the side surface R1c of the first conductive layer R1, and may cover a portion of the side surface R1c of the first conductive layer R1.

In some embodiments, the metal oxide layer R4 may include a lower surface R4a, an upper surface R4b, a first side surface R4c, and a second side surface R4d. The lower surface R4a of the metal oxide layer R4 may contact the touch-insulating layer 183, and the upper surface R4b of the metal oxide layer R4 is one surface opposing the lower surface R4a and may contact the third conductive layer R3. In addition, the first side surface R4c of the metal oxide layer R4 may contact the first conductive layer R1 and the second conductive layer R2, and the second side surface R4d of the metal oxide layer R4 is one surface opposing the first side surface R4c and may contact the touch protection layer 185. In one or more embodiments, an undercut UC may be formed between the third conductive layer R3 and the second side surface R4d of the metal oxide layer R4.

The metal oxide layer R4 may be formed by forming the first conductive layer R1, the second conductive layer R2, and the third conductive layer R3, and by then performing oxygen plasma treatment (O₂ plasma treatment) as a subsequent process in a fabricating process of the display device 10. The metal oxide layer R4 is not formed by depositing a separate material, and may be formed by performing first oxygen plasma treatment to oxidize copper (Cu) included in the first conductive layer R1 and the second conductive layer R2. However, the third conductive layer R3 of the display device 10 may have oxidation resistance, and thus, the metal oxide layer R4 may not be formed on the side surfaces R3c and the lower surface R3a of the third conductive layer R3 of the display device 10. The fabricating process will be described later.

The metal oxide layer R4 according to one or more embodiments may include copper oxide (CuOₓ). Because the copper oxide generally has blackened physical properties, the metal oxide layer R4 may have a very high extinction coefficient and low visible light reflectivity in a visible light region. As an example, the metal oxide layer R4 may have reflectivity of about 6% or less in the visible light region, but is not limited thereto.

In some embodiments, the metal oxide layer R4 may have a substantially uniform width Wr4 in the first direction (X-axis direction). This may mean that the metal oxide layer R4 is formed through oxygen plasma treatment. The width Wr4 of the metal oxide layer R4 may have a uniformity of about 5% or less. As an example, the width Wr4 of the metal oxide layer R4 may be about 100 Å or more and about 800 Å or less, but is not limited thereto. The width described above may be referred to as a thickness, an area, and the like, according to embodiments.

The display device 10 may solve a reflection defect due to the touch electrode, and may solve a reliability defect whereby a partial area of the display device 10 is viewed to be reddish from the outside of the display device 10, by including the metal oxide layer R4 located on the side surface R2c of the second conductive layer R2 including copper. In addition, the display device 10 may be easily fabricated by forming the metal oxide layer R4 through the oxygen plasma treatment.

In addition, the display device 10 according to one or more embodiments may have physical reliability by including the first conductive layer R1 having high adhesive strength with an inorganic layer, and may have electrical stability by including the third conductive layer R3 having the oxidation resistance.

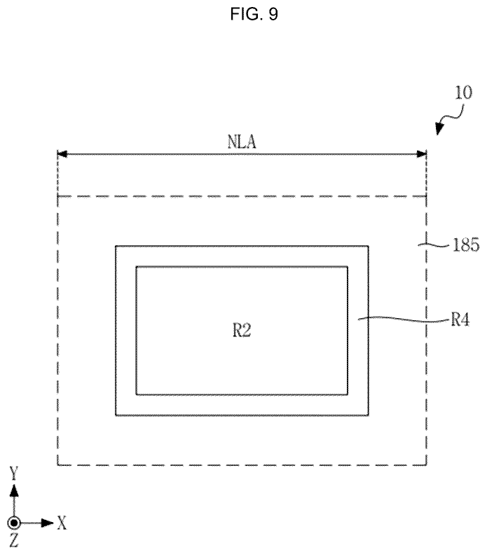

FIG. 9 is a plan view illustrating an arrangement of a second conductive layer and a metal oxide layer in FIG. 8.

Referring to FIG. 9, the metal oxide layer R4 according to one or more embodiments may be located in a portion overlapping the non-emission area NLA in plan view, and may expose the second conductive layer R2 while completely surrounding the second conductive layer R2 in plan view. In other words, the metal oxide layer R4 may expose the second conductive layer R2, and may be formed in a mesh shape, in plan view. The second conductive layer R2 exposed in plan view and the metal oxide layer R4 may be completely covered by the touch protection layer 185.

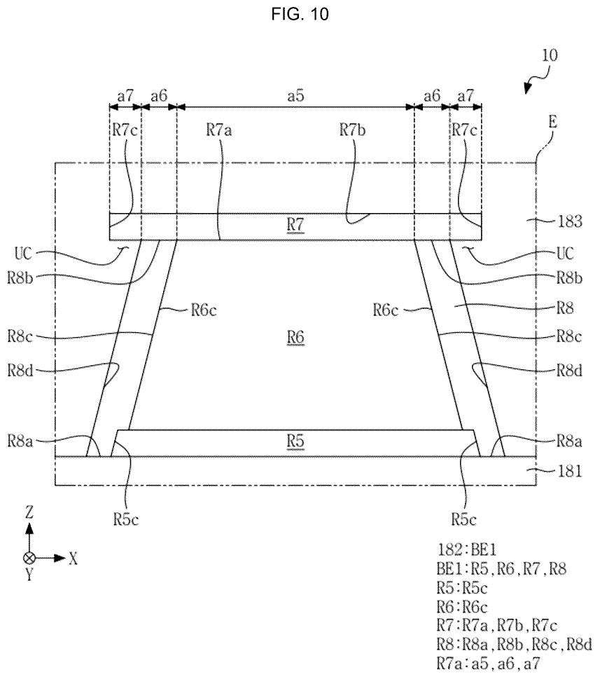

FIG. 10 is an enlarged cross-sectional view of area ‘E’ in FIG. 7. FIG. 10 is a schematic cross-sectional view of the first touch electrode in FIG. 7.

Referring to FIG. 10, the first touch electrode 182 according to one or more embodiments may include a first conductive layer R5, a second conductive layer R6, and a third conductive layer R7 that are stacked in the third direction (Z-axis direction), and a metal oxide layer R8 located on the second conductive layer R6 in the first direction (X-axis direction). The first connection electrode BE1 has been illustrated and then described in FIG. 10, but all touch electrodes included in the first touch electrode 182 may have the same structure and features.

The first conductive layer R5 according to one or more embodiments may be positioned on the touch buffer layer 181. The first conductive layer R5 may have high adhesive strength with the touch buffer layer 181. In other words, the first conductive layer R5 may have high adhesive strength with an inorganic insulating material.

The first conductive layer R5 included in the first touch electrode 182 may include the same material and height as the first conductive layer R1 included in the second touch electrode 184. As an example, the first conductive layer R5 may include a copper (Cu)-magnesium (Mg)-aluminum (Al) alloy (Cu—Mg—Al alloy). A portion of a side surface R5c of the first conductive layer R5 may be covered by the metal oxide layer R8. An overlapping description is omitted.

The second conductive layer R6 included in the first touch electrode 182 may include the same material and height as the second conductive layer R2 included in the second touch electrode 184. As an example, the second conductive layer R6 may include copper (Cu). A side surface R6c of the second conductive layer R6 may be entirely covered by the metal oxide layer R8. An overlapping description is omitted.

The third conductive layer R7 included in the first touch electrode 182 may include the same material, structure, and features as the third conductive layer R3 included in the second touch electrode 184. As an example, the third conductive layer R7 may include a molybdenum (Mo)-titanium (Ti)-nickel (Ni) alloy (MTD alloy). In addition, an undercut UC may be formed between the third conductive layer R7 and the side surface R6c of the second conductive layer R6.

In some embodiments, a lower surface R7a of the third conductive layer R7 may include a first portion a5, second portions a6, and third portions a7 corresponding to portions with which it is in contact. The first portion a5 may be a portion contacting the second conductive layer R6, the second portion a6 may be a portion contacting the metal oxide layer R8, and the third portion a7 may be a portion contacting the touch-insulating layer 183. The first portion a5 may be positioned between a plurality of second portions a6.

The metal oxide layer R8 included in the first touch electrode 182 may have the same material and width as the metal oxide layer R4 included in the second touch electrode 184. The metal oxide layer R8 may be located on the side surface R5c of the first conductive layer R5 and the side surface R6c of the second conductive layer R6 so as to contact the side surface R5c of the first conductive layer R5 and the side surface R6c of the second conductive layer R6.

In some embodiments, the metal oxide layer R8 may include a lower surface R8a, an upper surface R8b, a first side surface R8c, and a second side surface R8d. The lower surface R8a of the metal oxide layer R8 may contact the touch buffer layer 181, and the upper surface R8b of the metal oxide layer R8 is one surface opposing the lower surface R8a and may contact the third conductive layer R7. In addition, the first side surface R8c of the metal oxide layer R8 may contact the first conductive layer R5 and the second conductive layer R6, and the second side surface R8d of the metal oxide layer R8 is one surface opposing the first side surface R8c and may contact the touch-insulating layer 183. In one or more embodiments, an undercut UC may be formed between the third conductive layer R7 and the second side surface R8d of the metal oxide layer R8. An overlapping description is omitted.

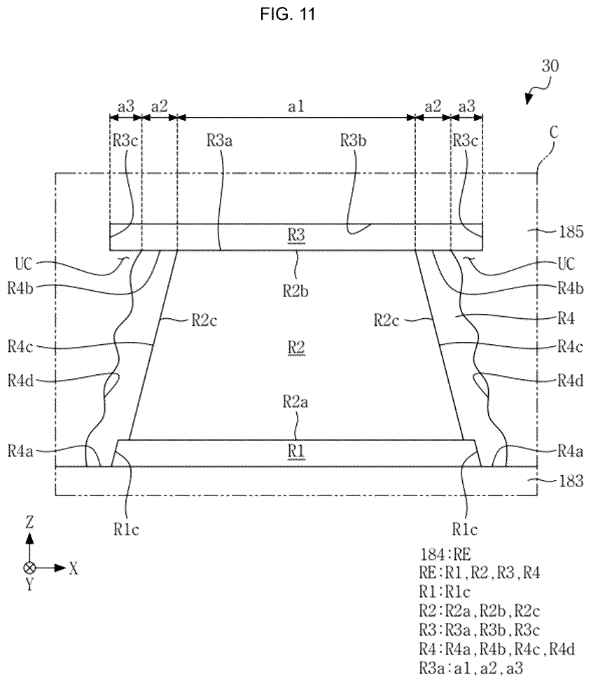

FIG. 11 is an enlarged cross-sectional view of area ‘C’ in FIG. 7 according to one or more other embodiments.

Referring to FIG. 11, a second touch electrode 184 of a display device 30 may have a different structure and features from the second touch electrode of the display device 10 illustrated in FIG. 8. Hereinafter, a repeated description of the display device 10 and the display device 30 is omitted, and differences between the display device 10 and the display device 30 will be described later.

In the display device 30, a metal oxide layer R4 included in the second touch electrode 184 includes an uneven surface that is irregularly arranged. It has been illustrated in FIG. 11 that a second side surface R4d includes an uneven surface that is irregularly arranged as a whole, but the present disclosure is not limited thereto. In the device 30, the second side surface R4d may also include an uneven surface only in at least a partial area thereof.

The uneven surface included in the metal oxide layer R4 may be formed depending on a process condition when oxygen plasma is injected in a fabricating process of the display device 30. As an example, the process condition may include a gas amount, a gas injection time, a position of a substrate, and the like.

The display device 30 may solve a reflection defect due to the touch electrode, and may solve a reliability defect that a partial area of the display device 30 is viewed to be reddish from the outside of the display device 30, by including the metal oxide layer R4 located on the side surface R2c of the second conductive layer R2 including copper and having unevenness. In addition, the display device 30 may be easily fabricated by forming the metal oxide layer R4 through the oxygen plasma treatment.

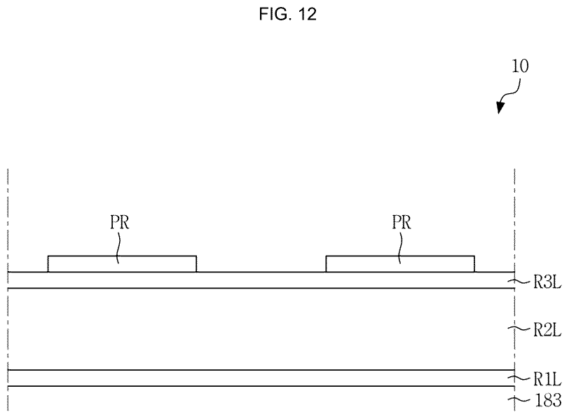

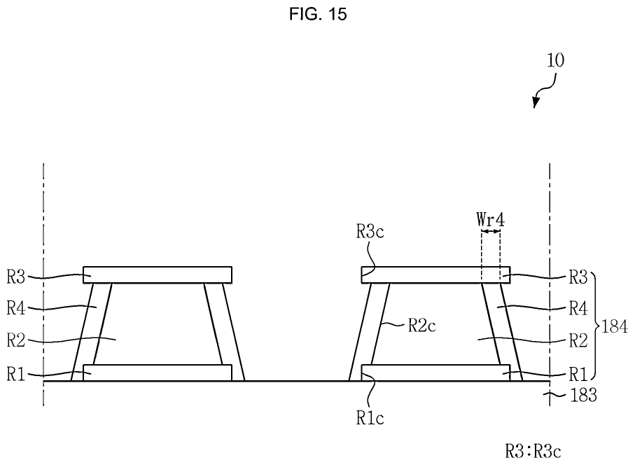

FIGS. 12 to 15 are views illustrating fabricating processes of a second touch electrode FIG. 8. Hereinafter, a method of fabricating the second touch electrode 184 included in the display device 10 will be described. The following description is only a description of some of fabricating processes of the second touch electrode 184, and processes for forming components described with reference to the present disclosure may be additionally performed before or after each operation. In addition, fabricating processes of the second touch electrode 184 known in the art may be additionally performed before or after each operation to be described below.

First, referring to FIG. 12, a first conductive material layer R1L, a second conductive material layer R2L, and a third conductive material layer R3L are formed on the touch-insulating layer 183 of the display device 10. The first conductive material layer R1L, the second conductive material layer R2L, and the third conductive material layer R3L may be sequentially stacked in the third direction (Z-axis direction).

Next, a plurality of photoresists PR are formed on the third conductive material layer R3L. The plurality of photoresists PR may be spaced apart from each other, and the third conductive material layer R3L that does not overlap the plurality of photoresists PR may be exposed.

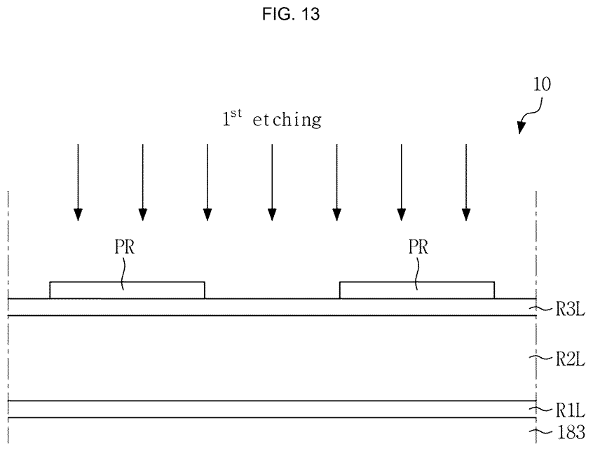

Subsequently, referring to FIG. 13, a first etching process (1^{st} etching) is performed using the plurality of photoresists PR as a mask. As an example, a wet etching process may be performed as the first etching process (1^{st} etching). In the present process, a portion of the third conductive material layer R3L positioned in a portion where the photoresists PR are not formed may be removed.

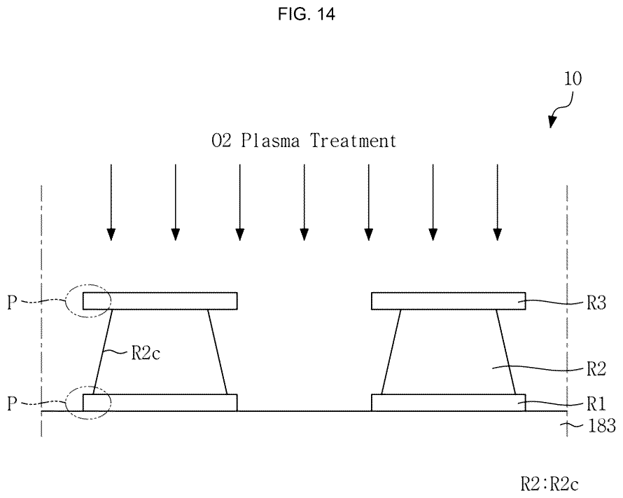

The first conductive material layer R1L, the second conductive material layer R2L, and the third conductive material layer R3L included in the display device 10 may include materials having different etch rates. As an example, the first conductive material layer R1L and the third conductive material layer R3L may have a lower etch rate than the second conductive material layer R2L with respect to an etchant used in the first etching process (1^{st} etching). Accordingly, as shown in FIG. 14, the first conductive material layer R1L and the third conductive material layer R3L may include portions P protruding more than a side surface R2c of the second conductive material layer R2L.

In the present process, the first conductive material layer R1L, the second conductive material layer R2L, and the third conductive material layer R3L may be formed in shapes of the first conductive layer R1, the second conductive layer R2, and the third conductive layer R3 illustrated in FIG. 8.

Next, referring to 14 and 15, the display device 10 may be placed into a deposition chamber and oxygen plasma treatment (O₂ plasma treatment) may be performed.

In the present process, the metal oxide layer R4 may be formed on the side surface R1c of the first conductive layer R1 and the side surface R2c of the second conductive layer R2. The metal oxide layer R4 is not formed through a separate deposition process, and may be formed by performing the oxygen plasma treatment in a state in which the first conductive layer R1, the second conductive layer R2, and the third conductive layer R3 are formed to oxidize copper (Cu) included in the first conductive layer R1 and the second conductive layer R2. However, the third conductive layer R3 of the display device 10 has oxidation resistance, and thus, the metal oxide layer R4 may not be formed on the side surfaces R3c of the third conductive layer R3.

In the present process, the metal oxide layer R4 may be formed to have a

substantially uniform width Wr4. The width Wr4 of the metal oxide layer R4 may be adjusted by a plasma process time, power, and the like. Accordingly, the second touch electrode 184 included in the display device 10 may be formed.

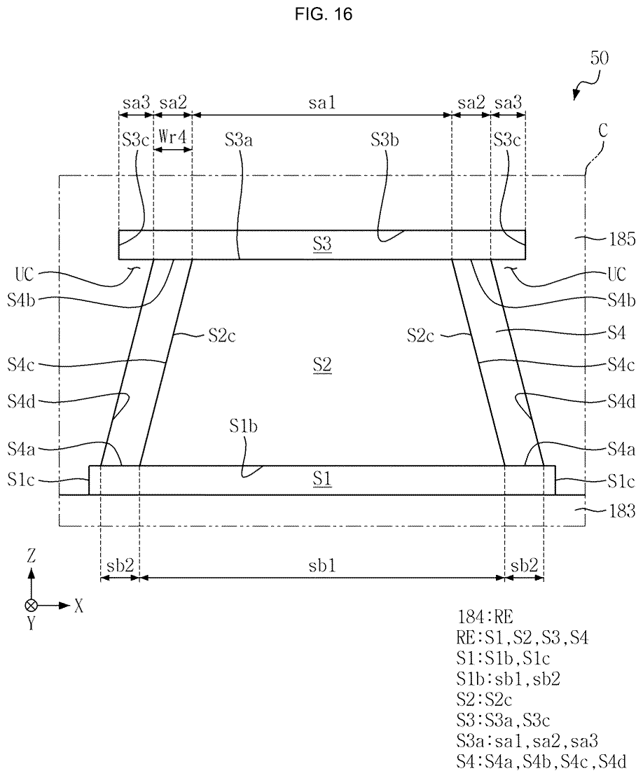

FIG. 16 is an enlarged cross-sectional view of area ‘C’ in FIG. 7 according to still one or more other embodiments.

Referring to FIG. 16, a second touch electrode 184 of a display device 50 may have a different structure and features from the second touch electrode of the display device 10 illustrated in FIG. 8. The sensing electrode RE of the second touch electrode 184 has been illustrated and then described in FIG. 16, but both the second touch electrode 184 and a first touch electrode 182 of the display device 50 may have the same structure and features. Hereinafter, a common description of the display device 10 and the display device 50 is omitted, and differences between the display device 10 and the display device 50 will be described later.

A first conductive layer S1 of the display device 50 may have high adhesive strength with the touch-insulating layer 183, and may have oxidation resistance. As an example, the first conductive layer S1 of the display device 50 may include at least one of a molybdenum (Mo)-titanium (Ti)-nickel (Ni) alloy (MTD alloy), indium (In)-gallium (Ga)-zinc (Zn) oxide (IGZO), or indium (In)-zinc (Zn) oxide (IZO). In a case where the first conductive layer S1 includes the molybdenum (Mo)-titanium (Ti)-nickel (Ni) alloy (MTD alloy), when the total number of atoms in the first conductive layer S1 is defined as 100 at %, the number of atoms of each of molybdenum (Mo), titanium (Ti), and nickel (Ni) may be about 25 at % or more and about 35 at % or less.

In some embodiments, the first conductive layer S1 of the display device 50 may include an upper surface S1b and side surfaces S1c. The side surface S1c of the first conductive layer S1 may protrude more than a side surface S2c of a second conductive layer S2, and may contact the touch protection layer 185.

Because the first conductive layer S1 of the display device 50 has the oxidation resistance, even though the first conductive layer S1 is exposed to oxygen plasma treatment, a metal oxide layer S4 may not be formed on the side surfaces S1c of the first conductive layer S1.

The upper surface S1b of the first conductive layer S1 is one surface facing the second conductive layer S2, and may include a first portion sb1 and second portions sb2 depending on structures with which it is in contact. The first portion sb1 may be a portion contacting the second conductive layer S2, and the second portion sb2 may be a portion contacting the metal oxide layer S4. The first portion sb1 of the display device 50 may be positioned between a plurality of second portions sb2.

The second conductive layer S2 of the display device 50 may be located on the first conductive layer S1 so as to contact the first conductive layer S1. The second conductive layer S2 may include a low-resistance metal material. The second conductive layer S2 of the display device 50 may include copper (Cu). However, the second conductive layer S2 of the display device 50 may further include molybdenum (Mo), aluminum (AI), chromium (Cr), gold (Au), titanium (Ti), nickel (Ni), neodymium (Nd), or the like, in addition to copper (Cu).

In some embodiments, the second conductive layer S2 may include side surfaces S2c. The side surface S2c of the second conductive layer S2 may be one surface contacting the metal oxide layer S4, and may be completely covered by the metal oxide layer S4. The side surface S2c included in the second conductive layer S2 of the display device 50 may be depressed more than the side surface S1c of the first conductive layer S1 in the first direction (X-axis direction).

A third conductive layer S3 of the display device 50 may be located on the second conductive layer S2 so as to contact the second conductive layer S2. The third conductive layer S3 of the display device 50 may have the same structure and features as the third conductive layer R3 included in the display device 10. An overlapping description is omitted.

In some embodiments, the third conductive layer S3 may include a lower surface S3a, an upper surface S3b, and side surfaces S3c. For example, the lower surface S3a of the third conductive layer S3 may be one surface contacting the second conductive layer S2, and the upper surface S3b of the third conductive layer S3 may be one surface opposing the lower surface S3a and contacting the touch protection layer 185. The side surface S3c included in the third conductive layer S3 may protrude in the first direction (X-axis direction) more than the side surface S2c included in the second conductive layer S2. Accordingly, an undercut UC may be formed between the third conductive layer S3 and the side surface S2c of the second conductive layer S2.

In some embodiments, the lower surface S3a of the third conductive layer S3 may include a first portion sa1, second portions sa2, and third portions sa3 depending on structures with which the lower surface S3a is in contact. In the display device 50, the first portion sa1 may be a portion contacting the second conductive layer S2, the second portion sa2 may be a portion contacting the metal oxide layer S4, and the third portion sa3 may be a portion contacting the touch protection layer 185. The first portion sa1 may be positioned between a plurality of second portions sa2, and the first portion sa1 and the second portions sa2 may be positioned between a plurality of third portions sa3.

The metal oxide layer S4 of the display device 50 may be located on the side surfaces S2c of the second conductive layer S2 so as to contact the side surfaces S2c of the second conductive layer S2, and may contact the upper surface S1b of the first conductive layer S1 and the lower surface S3a of the third conductive layer S3 in the third direction (Z-axis direction).

In some embodiments, the metal oxide layer S4 may include a lower surface S4a, an upper surface S4b, a first side surface S4c, and a second side surface S4d. The lower surface S4a of the metal oxide layer S4 may contact the first conductive layer S1, and the upper surface S4b of the metal oxide layer S4 is one surface opposing the lower surface S4a and may contact the third conductive layer S3. In addition, the first side surface S4c of the metal oxide layer S4 may contact the second conductive layer S2, and the second side surface S4d of the metal oxide layer S4 is one surface opposing the first side surface S4c and may contact the touch protection layer 185.

In some embodiments, a width Wr4 of the metal oxide layer S4 may be substantially uniform. A description of overlapping contents is omitted.

The metal oxide layer S4 of the display device 50 may be formed by forming the first conductive layer S1, the second conductive layer S2, and the third conductive layer S3, and by then performing oxygen plasma treatment as a subsequent process in a fabricating process of the display device 50. In the fabricating process of the display device 50, the first conductive layer S1 and the third conductive layer S3 have the oxidation resistance, and thus, the metal oxide layer S4 may not be formed on the side surfaces S1c of the first conductive layer S1 and the side surfaces S3c of the third conductive layer S3.

The display device 50 may solve a reflection defect due to the touch electrode, and may solve a reliability defect that a partial area of the display device 50 is viewed to be reddish from the outside of the display device 50, by including the metal oxide layer S4 located on the second conductive layer S2 including copper. In addition, the display device 50 may be easily fabricated by forming the metal oxide layer S4 through the oxygen plasma treatment. In addition, the display device 50 may have physical reliability by including the first conductive layer S1 having high adhesive strength with an inorganic layer, and may have electrical stability by including the first conductive layer S1 and the third conductive layer S3 having the oxidation resistance.

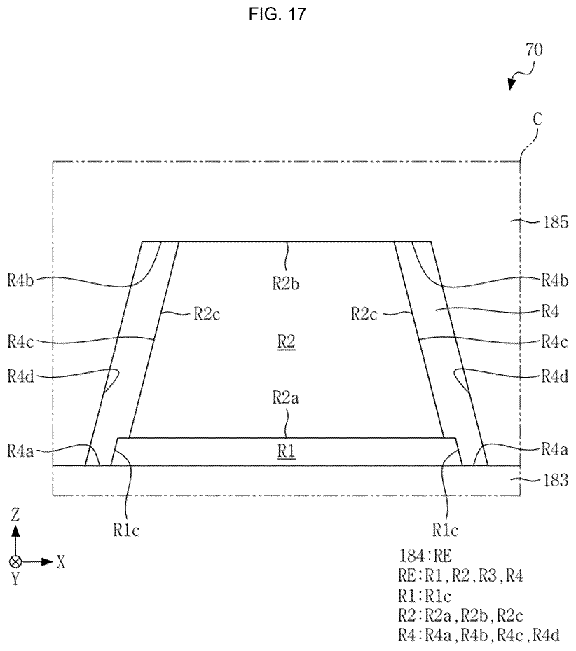

FIG. 17 is an enlarged cross-sectional view of area ‘C’ in FIG. 7 according to still one or more other embodiments.

Referring to FIG. 17, a second touch electrode 184 included in a display device 70 may have a different structure and features from the second touch electrode 184 included in the display device 10 illustrated in FIG. 8. For example, the second touch electrode 184 of the display device 70 is different from the second touch electrode 184 of the display device 10 in that it does not include the third conductive layer R3 illustrated in FIG. 8. Hereinafter, a repeated description of the display device 10 and the display device 70 is omitted, and differences between the display device 10 and the display device 70 will be described later.

The second touch electrode 184 of the display device 70 may include a first conductive layer R1 and a second conductive layer R2 that are stacked in the third direction (Z-axis direction), and a metal oxide layer R4 located on the second conductive layer R2 in the first direction (X-axis direction). The sensing electrode RE of the second touch electrode 184 has been illustrated and then described in FIG. 17, but both the second touch electrode 184 and a first touch electrode 182 of the display device 70 may have the same structure and features.

The first conductive layer R1 of the display device 70 may be positioned on the touch-insulating layer 183. The first conductive layer R1 may have high adhesive strength with the touch-insulating layer 183. In other words, the first conductive layer R1 may have high adhesive strength with an inorganic insulating material. The adhesive strength between the first conductive layer R1 and the touch-insulating layer 183 of the display device 70 may be higher than adhesive strength between the second conductive layer R2 and the touch protection layer 185, and the metal oxide layer R4 and the touch-insulating layer 183.

The first conductive layer R1 may include a conductive metal material. As an example, the first conductive layer R1 may include titanium (Ti). In some embodiments, the first conductive layer R1 may include side surfaces R1c. The side surface R1c of the first conductive layer R1 may be covered by a metal oxide layer R4 to be described later.

The second conductive layer R2 of the display device 70 may include the same material as the second conductive layer R2 of the display device 10 illustrated in FIG. 8. As an example, the second conductive layer R2 may include copper (Cu).

In some embodiments, the second conductive layer R2 of the display device 70 may include an upper surface R2b, a lower surface R2a, and side surfaces R2c. The lower surface R2a of the second conductive layer R2 may be one surface contacting the first conductive layer R1, and the upper surface R2b of the second conductive layer R2 may be one surface opposing the lower surface R2a and contacting the touch protection layer 185. In addition, the side surface R2c of the second conductive layer R2 may be one surface connecting the upper surface R2b and the lower surface R2a to each other in the first direction (X-axis direction), and may be one surface contacting a metal oxide layer R4 to be described later. The side surface R2c of the second conductive layer R2 may be completely covered by the metal oxide layer R4.

The metal oxide layer R4 of the display device 70 may include the same material as the metal oxide layer R4 of the display device 10 illustrated in FIG. 8. A description of overlapping contents is omitted.

The metal oxide layer R4 of the display device 70 may be located on the side surface R2c of the second conductive layer R2 so as to contact the side surface R2c of the second conductive layer R2, and may entirely cover the side surface R2c of the second conductive layer R2. In addition, the metal oxide layer R4 may be located on the side surface R1c of the first conductive layer R1 so as to contact the side surface R1c of the first conductive layer R1, and may cover a portion of the side surface R1c of the first conductive layer R1.

The metal oxide layer R4 may not be positioned on the upper surface R2b of the second conductive layer R2. This may be caused by performing a process of forming a photoresist on the second conductive layer R2, and by then forming the metal oxide layer R4 in a fabricating process of the display device 70. The fabricating process will be described later.

In some embodiments, the metal oxide layer R4 may include a lower surface R4a, an upper surface R4b, a first side surface R4c, and a second side surface R4d. The lower surface R4a of the metal oxide layer R4 may contact the touch-insulating layer 183, and the upper surface R4b of the metal oxide layer R4 is one surface opposing the lower surface R4a, and may contact the touch protection layer 185. In addition, the first side surface R4c of the metal oxide layer R4 may contact the first conductive layer R1 and the second conductive layer R2, and the second side surface R4d of the metal oxide layer R4 is one surface opposing the first side surface R4c and may contact the touch protection layer 185.

The display device 70 may solve a reflection defect due to the touch electrode, and may solve a reliability defect that a partial area of the display device 70 is viewed to be reddish from the outside of the display device 70, by including the metal oxide layer R4 located on the second conductive layer R2 including copper. In addition, the display device 70 may be easily fabricated by forming the metal oxide layer R4 through the oxygen plasma treatment.

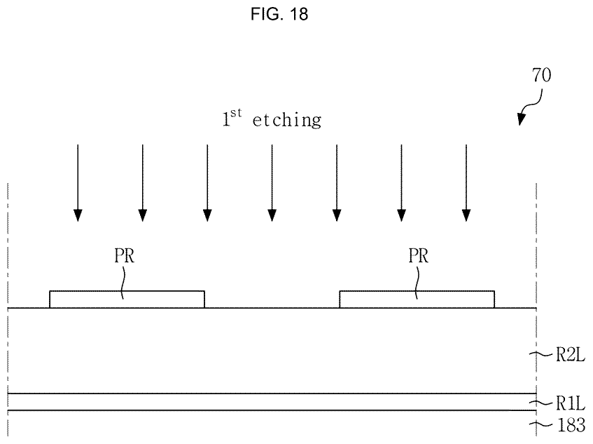

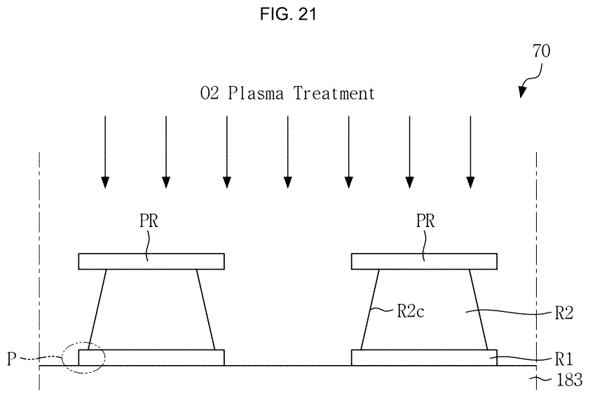

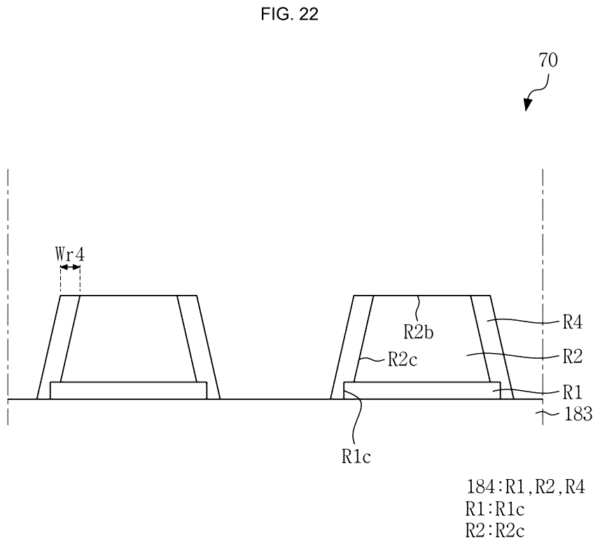

FIGS. 18 to 22 are views illustrating fabricating processes of a second touch electrode 184 included in a display device 70 of FIG. 17. Hereinafter, a method of fabricating the second touch electrode 184 included in the display device 70 will be described. The following description is only a description of some of fabricating processes of the second touch electrode 184, and processes for forming components described with reference to the present disclosure may be additionally performed before or after each operation. In addition, fabricating processes of the second touch electrode 184 known in the art may be additionally performed before or after each operation to be described below.

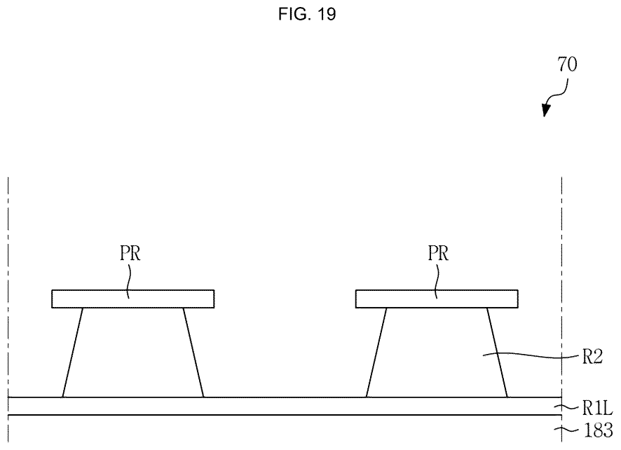

First, referring to FIGS. 18 and 19, a first conductive material layer R1L and a second conductive material layer R2L are formed on the touch-insulating layer 183 of the display device 70. The first conductive material layer R1L and the second conductive material layer R2L may be sequentially stacked in the third direction (Z-axis direction).

Next, a plurality of photoresists PR are formed on the second conductive material layer R2L. The plurality of photoresists PR may be spaced apart from each other, and the second conductive material layer R2L that does not overlap the plurality of photoresists PR may be exposed.

Subsequently, a first etching process (1^{st} etching) is performed using the

plurality of photoresists PR as a mask. As an example, a wet etching process may be performed as the first etching process (1^{st} etching). In the present process, the second conductive material layer R2L positioned in a portion where the photoresists PR are not formed may be selectively removed. Through the present process, the second conductive material layer R2L may be formed as the second conductive layer R2 of the display device 70, and the first conductive material layer R1L may remain without being removed.

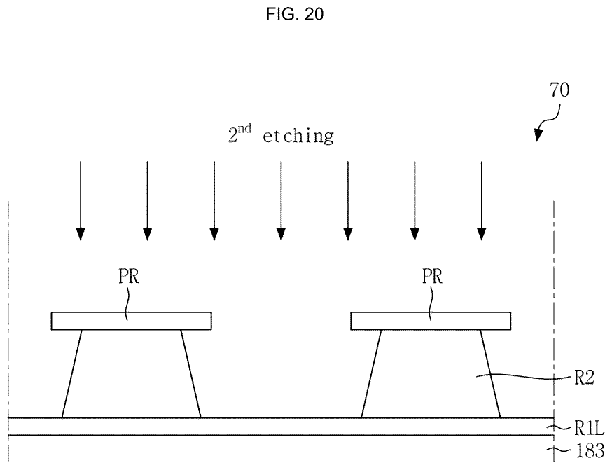

Next, referring to FIGS. 20 to 22, a plurality of photoresists PR are formed on the second conductive layer R2. The plurality of photoresists PR may be spaced apart from each other, and the first conductive material layer R1L that does not overlap the plurality of photoresists PR may be exposed.

Subsequently, a second etching process (2^{nd} etching) is performed using the plurality of photoresists PR as a mask. As an example, a dry etching process may be performed as the second etching process (2^{nd} etching). In the present process, the first conductive material layer R1L positioned in a portion where the photoresists PR are not formed may be removed, and accordingly, the first conductive layer R1 of the display device 70 illustrated in FIG. 17 may be formed.

In the present process, the first conductive layer R1 may have a portion P protruding more than the side surface R2c of the second conductive layer R2.

Next, the display device 70 may be placed into a deposition chamber, and oxygen plasma treatment (O₂ plasma treatment) may be performed. In the present process, the metal oxide layer R4 may be formed on the side surface R1c of the first conductive layer R1 and the side surface R2c of the second conductive layer R2. The metal oxide layer R4 is not formed through a separate deposition process, and may be formed by oxidizing copper (Cu) included in the first conductive layer R1 and the second conductive layer R2. In the present process, the metal oxide layer R4 may be formed to have a substantially uniform width Wr4. The width Wr4 of the metal oxide layer R4 may be adjusted by a plasma process time, power, and the like.

In the present process, the upper surface R2b of the second conductive layer R2 is covered by the photoresist PR, and thus, the metal oxide layer R4 may not be formed on the second conductive layer R2. Accordingly, the second touch electrode 184 included in the display device 70 may be formed.

The foregoing is illustrative of some embodiments of the present disclosure,

and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising an emission area and a non-emission area;
a touch-insulating layer above the substrate;
a touch electrode above the touch-insulating layer, overlapping the non-emission area, and comprising:
a first conductive layer contacting the touch-insulating layer;
a second conductive layer above the first conductive layer, and comprising a conductive material that is different from a conductive material of the first conductive layer; and
a metal oxide layer on a side surface of the second conductive layer facing the emission area, contacting the side surface of the second conductive layer, and not contacting an upper surface of the second conductive layer facing a touch protection layer; and
a touch protection layer above the touch-insulating layer and the touch electrode.

2. The display device of claim 1, wherein the second conductive layer comprises copper, and
wherein the metal oxide layer comprises copper oxide.

3. The display device of claim 2, wherein the metal oxide layer entirely covers the side surface of the second conductive layer.

4. The display device of claim 3, wherein a width of the metal oxide layer in a direction parallel to the substrate is substantially uniform within about 5%.

5. The display device of claim 4, wherein a height of the first conductive layer in a direction perpendicular to the substrate is less than a height of the second conductive layer.

6. The display device of claim 4, wherein the first conductive layer comprises any one of a molybdenum-titanium-nickel alloy (MTD alloy), titanium, or a copper-magnesium-aluminum alloy.

7. The display device of claim 4, wherein the first conductive layer comprises a protrusion portion protruding more than the side surface of the second conductive layer in the direction parallel to the substrate.

8. The display device of claim 1, wherein the touch electrode further comprises a third conductive layer above the second conductive layer and the metal oxide layer, and comprising a lower surface facing the second conductive layer and the metal oxide layer and forming an undercut.

9. The display device of claim 8, wherein the lower surface of the third conductive layer comprises a first portion contacting the second conductive layer, a second portion contacting the metal oxide layer, and a third portion contacting the touch protection layer.

10. The display device of claim 9, wherein the second portion is positioned between the first portion and the third portion.

11. The display device of claim 10, wherein the third conductive layer comprises a molybdenum-titanium-nickel alloy (MTD alloy).

12. The display device of claim 10, wherein the metal oxide layer contacts a side surface of the first conductive layer.

13. The display device of claim 10, wherein the metal oxide layer does not contact a side surface of the first conductive layer.

14. The display device of claim 10, wherein a surface of the metal oxide layer facing the emission area comprises an uneven surface.

15. The display device of claim 1, wherein the metal oxide layer exposes the second conductive layer, and entirely surrounds the second conductive layer in plan view.

16. The display device of claim 15, wherein the metal oxide layer has a mesh shape defining openings in plan view.

17. A method of fabricating a display device, the method comprising:
forming a first conductive material layer above a substrate comprising an emission area and a non-emission area;
forming a second conductive material layer above the first conductive material layer;
forming photoresists above the second conductive material layer and overlapping the non-emission area;
performing a first etching process to form a second conductive layer;
forming photoresists above the second conductive layer and overlapping the non-emission area;
performing a second etching process to form a first conductive layer; and
performing oxygen plasma treatment to form a metal oxide layer on a side surface of the first conductive layer and on a side surface of the second conductive layer.

18. The method of fabricating the display device of claim 17, wherein the first etching process comprises a wet etching process, and
wherein the second etching process comprises a dry etching process.

19. The method of fabricating the display device of claim 17, wherein the first conductive layer comprises a protrusion portion protruding more than the side surface of the second conductive layer.

20. The method of fabricating the display device of claim 19, wherein the first conductive layer and the second conductive layer comprise copper, and
wherein the metal oxide layer comprises copper oxide.
